(19) United States
(12) Patent Application Publication
(10) Pub. No.: US 2006/0019181 A1
(43) Pub. Date: Jan. 26, 2006

(54) [METHOD OF MANUFACTURING COLOR FILTER ARRAY AND THIN FILM]

(76) Inventors: Chia-Te Lin, Chiayi County (TW); Da-Shuang Kuan, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/710,599

(22) Filed: Jul. 23, 2004

(51) Int. Cl. G02B 5/20; G03F 7/00

(52) U.S. Cl. 430/7; 430/324

(57) ABSTRACT

A method of manufacturing a color filter array is provided. The manufacturing method is as follows. Step (a), form a patterned first photoresist layer over a substrate. The patterned first photoresist layer has a plurality of openings that exposes a portion of the substrate. Step (b), form a filter material layer on the exposed area of the substrate. Step (c), form a second photoresist layer on the filter material layer. Step (d), remove the first and the second photoresist layer such that the filter material layer forms a plurality of first filter films. Step (e), repeat step (a) to (c) at least once and remove the first and the second photoresist layer to form a plurality of second filter films in areas except the first color filter films. The aforementioned method of forming the color filter array can form filter films having perpendicular sidewalls on the substrate.

### BACKGROUND OF INVENTION

1. Field of the Invention

The present invention relates to a method of manufacturing a thin film. More particularly, the present invention relates to a method of manufacturing a color filter film on a substrate (color filter array).

2. Description of the Related Art

With the increase in the capability of computers and the progress in networking and multimedia techniques, image data are now mostly transmitted in a digital rather than analogue format. To fit our modern lifestyle, video or imaging equipment is becoming lighter and slimmer. Although the conventional cathode ray tube (CRT) has many advantages, the design of the electron gun renders it heavy and bulky. Moreover, there is always some danger of hurting viewer”s eyes due to the emission of a little radiation. With big leaps in the techniques of manufacturing semiconductor devices and opto-electronic devices, flat panel displays such as liquid crystal displays (LCD), organic light-emitting displays (OLED) and plasma display panel (PDP) have gradually become mainstream display products.

In general, liquid display devices can be divided into direct viewing displays such as liquid crystal display monitors and digital liquid crystal televisions and indirect viewing displays applied in liquid crystal projectors and back projection televisions. In recent years, liquid crystal displays are aiming towards the provision of full coloration, a large screen, a high resolution and a low production cost. However, direct viewing displays have many restrictions with regards to screen size and production cost. Thus, a reflective-micro display panel with a high resolution such as a liquid crystal on silicon (LCOS) display panel together with an optical engine are often used to produce a liquid crystal projector and back projection television having a large screen.

LCOS panel is a reflective type liquid crystal panel set up on a silicon substrate. In a LCOS panel, metal-oxide-semiconductor (MOS) transistors are formed on the silicon substrate for controlling the liquid crystal layer above various pixel electrodes. In addition, the pixel electrodes of the LCOS panel are fabricated using a metallic material so that incident light passing through the liquid crystal layer from an external light source can be reflected back to emerge from the color filter array for display. Because the LCOS panel is set up on a silicon substrate, the LCOS panel occupies a volume smaller than a conventional direct viewing display panel and yet has a higher resolution. In other words, the LCOS panel is particularly suitable for producing projection displays with a large screen.

Nowadays, the color filter array of a LCOS panel is still fabricated using a conventional process. However, as the resolution of the LCOS panel continues to increase while the panel is miniaturized, the conventional method of fabricating the color filter array can no longer meet the precision required.

FIGS. 1A through 1D are schematic cross-sectional views showing the steps for fabricating a conventional color filter array. As shown in FIG. 1A, a filter material layer 102a is formed over a glass substrate 100. As shown in FIG. 1B, a patterned photoresist layer 110 is formed over the filter material layer 102a. The photoresist layer 110 exposes a portion of the filter material layer 102a. Thereafter, as shown in FIG. 1C, the exposed filter material layer 102a is removed. As shown in FIG. 1D, after removing the photoresist layer 110, the exposed filter material layer 102a forms a plurality of color filter films 102. Similarly, other color filter films are formed over the glass substrate 100.

It should be noted that the filter material layer in the aforementioned process of forming the color filter array is removed by an etching process. However, the process of removing the filter material layer often leads to overetching. Furthermore, the solution for etching the filter material layer is not an anisotropic etching solution and hence a color filter film with vertical sidewalls is hard to produce. Consequently, as the demands for display panels having a higher resolution and a smaller size continue to increase, light leak at the edge of the color filter film due to scattering will intensify. Ultimately, the display quality of micro-displays will also be affected.

### SUMMARY OF INVENTION

Accordingly, at least one objective of the present invention is to provide a method of manufacturing color filter films on a substrate such that the color filter films have vertical sidewalls for producing a better display quality.

At least a second objective of the present invention is to provide a method of manufacturing thin films such that two photoresist processes are used to produce vertical sidewalls at the edge of the films and the photoresist layers in the photoresist processes are used to protect the films.

To achieve these and other advantages and in accordance with the purpose of the invention, as embodied and broadly described herein, the invention provides a method of manufacturing a color filter array. The manufacturing method is as follows. Step (a), form a patterned first photoresist layer over a substrate. The patterned first photoresist layer has a plurality of openings that exposes a portion of the substrate. Step (b), form a filter material layer on the exposed area of the substrate. Step (c), form a second photoresist layer on the filter material layer. Step (d), remove the first and the second photoresist layer such that the filter material layer forms a plurality of first filter films. Step (e), repeat step (a) to (c) at least once and remove the first and the second photoresist layer to form a plurality of second filter films in areas except the first color filter films.

In one preferred embodiment of the present invention, the filter material layer also forms over the first photoresist layer. Furthermore, after the step (c), further includes a step (c1) of removing the filter material layer above the first photoresist layer. In addition, the filter material layer has a thickness smaller than or equal to the first photoresist layer.

The present invention also provides a method of manufacturing thin films. The manufacturing method is as follows. Step (a), form a patterned first photoresist layer over a substrate. The patterned first photoresist layer has a plurality of openings that exposes a portion of the substrate. Step (b), form a material layer on the exposed area of the substrate. Step (c), form a second photoresist layer on the material layer. Step (d), remove the first and the second photoresist layer such that the material layer forms a plurality of thin films.

In one preferred embodiment of the present invention, the material layer also forms over the first photoresist layer. Furthermore, after the step (c), further includes a step (c1) of removing the material layer above the first photoresist layer. In addition, the material layer has a thickness smaller than or equal to the first photoresist layer.

In brief, the method of fabricating the color filter array and thin films according to the present invention includes forming a patterned first photoresist layer over a substrate and then forming thin films inside the openings in the first photoresist layer. Therefore, shaped by the first photoresist layer, the thin films have vertical sidewalls. Furthermore, the second photoresist layer covers the thin films inside the opening and prevents the thin films from any attack by etching solution when the material layer on the first photoresist layer is removed. Thus, the present invention not only provides a thin film with vertical sidewalls, but also provides a method of fabricating an ideal color filter film on a substrate to improve the display quality of a display panel.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1D are schematic cross-sectional views showing the steps for fabricating a conventional color filter array.

FIGS. 2A through 21 are schematic cross-sectional views showing the steps for fabricating a color filter array according to one preferred embodiment of the present invention.

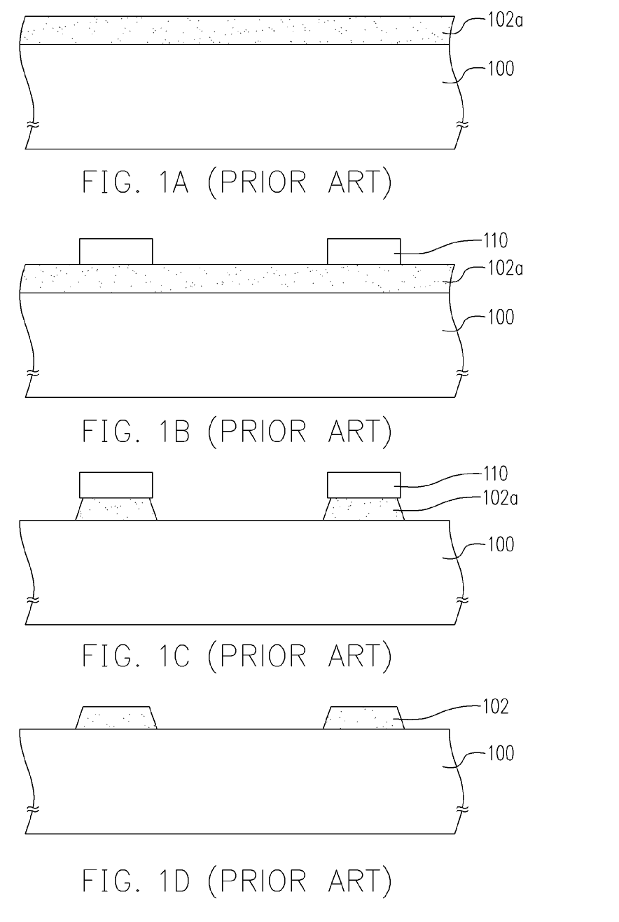

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

The present invention not only provides a method of fabricating a color filter array, but also provides a method of fabricating a thin film. However, since the method of fabricating a thin film is subsumed under the fabrication of the color filter array, only the process of fabricating the color filter array is described in the following.

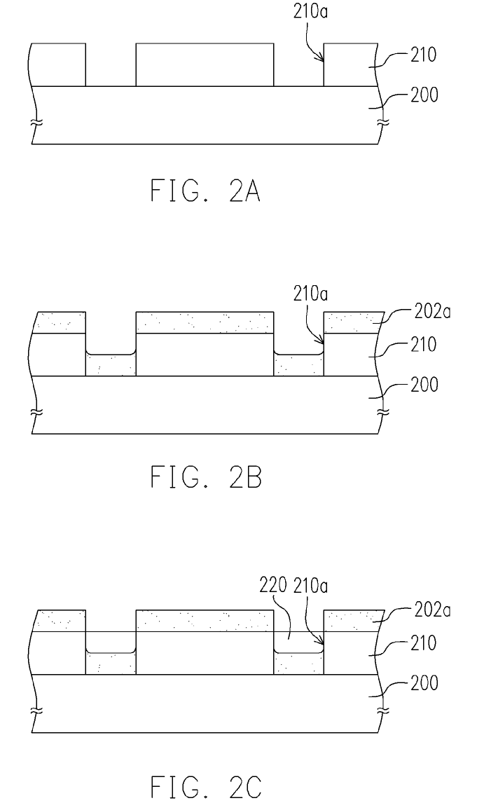

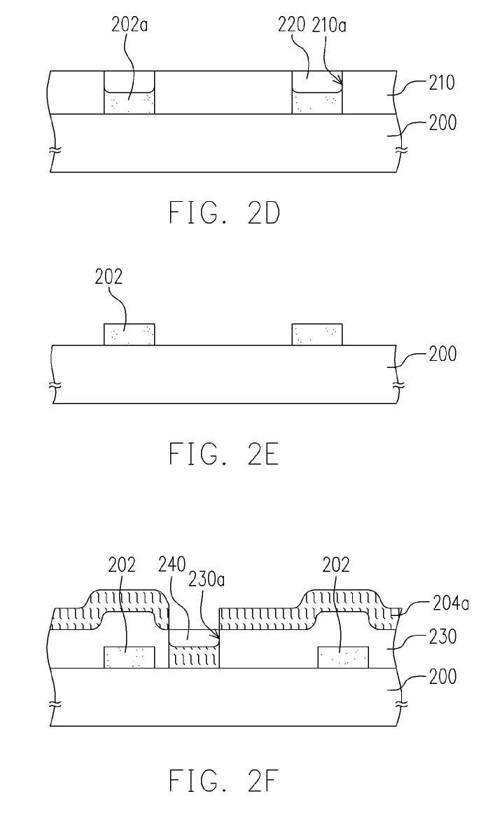

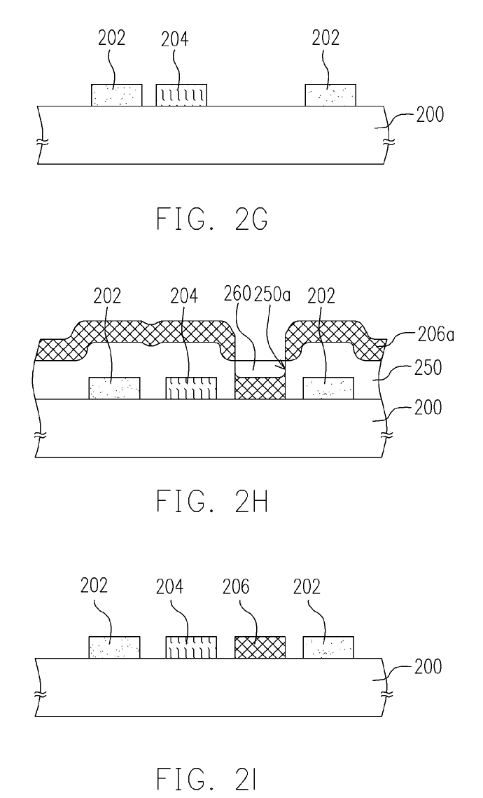

FIGS. 2A through 21 are schematic cross-sectional views showing the steps for fabricating a color filter array according to one preferred embodiment of the present invention. As shown in FIG. 2A, a patterned first photoresist layer 210 is formed over a substrate 200. The first photoresist layer 210 has a plurality of openings 210a that exposes a portion of the substrate 200 and the substrate 200 is a glass plate, for example. The first photoresist layer 210 is formed, for example, by coating a positive photoresist or a negative photoresist layer over the substrate 200 and performing a photolithographic process to define the openings 210a.

As shown in FIG. 2B, a first filter material layer 202a is formed over the substrate 200. The first filter material layer 202a covers the first photoresist layer 210 and the exposed substrate 200 within the openings 210a. Due to the step height between the top surface of the first photoresist layer 210 and the top surface of the substrate 200, the first filter material layer 202a within the openings 210a may separate from the first filter material layer 202a on the first photoresist layer 210. Furthermore, through the openings 210a in the first photoresist layer 210, the sidewalls of the first filter material layer 202a are close to vertical. It should be noted that the thickness of the first filter material layer 202a is smaller than or equal to the thickness of the first photoresist layer 210 in one embodiment of the present invention. As a result, the first filter material layer 202a within the openings 210a and the first filter material layer 202a on the first photoresist layer 210 are more sharply detached from each other.

As shown in FIG. 2C, a patterned second photoresist layer 220 is formed over the substrate 200. The second photoresist layer 220 covers the first filter material layer 202a inside the openings 210a but exposes the first filter material layer 202a over the photoresist layer 210. The second photoresist layer 220 and the first photoresist layer 210 are positive photoresist or negative photoresist layer, for example. Similarly, the second photoresist layer 220 is patterned using photolithographic processes, for example.

As shown in FIG. 2D, the first filter material layer 202a over the first photoresist layer 210 is removed. The method of removing the first filter material layer 202a includes, for example, performing a chemical etching process. Because the second photoresist layer 220 covers the first filter material layer 202a inside the openings 210a, the first filter material layer 202a underneath the second photoresist layer 220 is protected from the etching solution. In other words, only the first filter material layer 202a over the first photoresist layer 210 is removed after the etching process.

As shown in FIG. 2E, the first photoresist layer 210 and the second photoresist layer 220 are removed. The first filter material layer 202a originally inside the openings 210a and protected by the second photoresist layer 220 is exposed to form a plurality of first color filter films 202.

After the completion of steps as shown in FIGS. 2A through 2E, a plurality of first color filter films is formed on the substrate. To form a complete color filter array (having three colors red, green and blue), the aforementioned procedure must be repeated at least twice. In other words, color filter films of other colors must be formed on the substrate except the regions occupied by the first color filter films. In the following, the steps for fabricating other color filter films are described. Since the structure and manufacturing method of the other thin films is similar to the ones already described in FIGS. 2A through 2E, detailed description is omitted.

As shown in FIG. 2F, a patterned third photoresist layer 230 is formed over the substrate 200. The third photoresist layer 230 covers the first color filter films 202. Furthermore, the third photoresist layer 230 has a plurality of openings 230a that exposes a portion of the substrate 200 except the first color filter films 202 occupied areas. Thereafter, a second filter material layer 204a is formed over the substrate 200 to cover the third photoresist layer 230 and the exposed substrate 200 within the openings 230a. A patterned fourth photoresist layer 240 is formed over the second filter material layer 204a inside the openings. 230a.

As shown in FIG. 2G, the second filter material layer 204a over the third photoresist layer 230 is removed. Thereafter, the third photoresist layer 230 and the fourth photoresist layer 240 are removed to form a plurality of second color filter films 204 over the substrate 200.

As shown in FIG. 2H, a patterned fifth photoresist layer 250 is formed over the substrate 200. The fifth photoresist layer 250 covers the first color filter films 202 and the second color filter films 204. Furthermore, the fifth photoresist layer 250 has a plurality of openings 250a that exposes a portion of the substrate 200 except the occupied areas of the first color filter films 202 and the second color filter films 204. Thereafter, a third filter material layer 206a is formed over the substrate 200 to cover the fifth photoresist layer 250 and the exposed substrate 200 within the openings 250a. A patterned sixth photoresist layer 260 is formed over the third filter material layer 206a inside the openings 250a.

As shown in FIG. 21, the third filter material layer 206a over the fifth photoresist layer 250 is removed. Thereafter, the fifth photoresist layer 250 and the sixth photoresist layer 260 are removed to form a plurality of third color filter films 206 over the substrate 200.

In summary, the method of fabricating the color filter array and thin films according to the present invention includes forming a patterned photoresist layer over a substrate and then forming thin films inside the openings in the first photoresist layer. Therefore, shaped by the photoresist layer, the films can have vertical sidewalls. Furthermore, after filling the openings with filter material, another photoresist layer covers the thin films inside the opening. Hence, the thin films are prevented from any attack by etching solution in a subsequent etching process. Thus, the present invention not only provides a thin film with vertical sidewalls, but also provides a method of fabricating an ideal color filter film on a substrate to improve the display quality of a display panel.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A method of manufacturing a color filter array, comprising the steps of:
(a) forming a patterned first photoresist layer over a substrate, wherein the first photoresist layer has a plurality of openings with each opening exposing a portion of the substrate;
(b) forming a filter material layer over the exposed substrate within the openings;
(c) forming a second photoresist layer over the filter material layer;
(d) removing the first photoresist layer and the second photoresist layer to form a plurality of first color filter films; and
(e) repeating the steps from (a) to (c) at least once and removing the first photoresist layer and the second photoresist layer to form a plurality of second color filter films on the substrate in areas except the first color filter films.

2. The method of claim 1, wherein the step of forming the filter material layer over the exposed substrate within the openings further comprises covering the first photoresist layer with the filter material layer.

3. The method of claim 2, wherein after carrying out step (c), further comprises:
(c1) removing the filter material layer over the first photoresist layer.

4. The method of claim 1, wherein the filter material layer has a thickness smaller than the first photoresist layer.

5. The method of claim 1, wherein the filter material layer has a thickness equal to the first photoresist layer.

6. A method of manufacturing a thin film on a substrate, comprising the steps of:
(a) forming a patterned first photoresist layer over the substrate, wherein the first photoresist layer has a plurality of openings with each opening exposing a portion of the substrate;
(b) forming a material layer over the exposed substrate within the openings;
(c) forming a second photoresist layer over the material layer; and
(d) removing the first photoresist layer and the second photoresist layer to form a plurality of thin films.

7. The method of claim 6, wherein the step of forming the material layer over the exposed substrate within the openings further comprises covering the first photoresist layer with the material layer.

8. The method of claim 7, wherein after carrying out step (c), further comprises:
(c1) removing the material layer over the first photoresist layer.

9. The method of claim 6, wherein the material layer has a thickness smaller than the first photoresist layer.

10. The method of claim 6, wherein the material layer has a thickness equal to the first photoresist layer.
